(19) United States
(12) Patent Application Publication
(10) Pub. No.: US 2004/0092072 A1
(43) Pub. Date: May 13, 2004

(54) Arrangements having increased on-die capacitance

(76) Inventor: Sarah E. Kim, Portland, OR (US)

Correspondence Address: EDWIN H. TAYLOR, BLAKELY, SOKOLOFF, TAYLOR & ZAFMAN LLP, 12400 WILSHIRE BOULEVARD, SEVENTH FLOOR, LOS ANGELES, CA, 90025, US

(21) Appl. No.: 10/289,437

(22) Filed: Nov. 7, 2002

(51) Int. Cl. H01L 21/8234; H01L 21/8244; H01L 21/8242; H01L 21/20

(52) U.S. Cl. 438/255; 438/398

(57) ABSTRACT

Arrangements having increased on-die capacitance.

### FIELD

The present invention is directed to arrangements having increased on-die capacitance.

### BACKGROUND

Background and example embodiments may be described using the context of processors and die (chip) packages, but practice of the present invention and a scope of the claims are not limited thereto.

Recent marketplace requirements have necessitated chip designs with higher-and-higher operating frequencies (e.g., 3, 4, . . . Ghz). In turn, increased operating frequencies typically result in increased power requirements. An effectiveness and popularity (i.e., widespread use) of a processor or other integrated circuit (IC) chips may depend on power characteristics of the chip (e.g., direct current (DC) voltage drop through package-level interconnects, maximum interconnect current carrying capability, and alternating current (AC) performance, e.t.c.). Design of the chip to mitigate inductance and voltage noise may be critical in achieving effective power usage.

One way to increase speed is to make chip components smaller-and-smaller (so that signals have shorter distances to travel and quicker switching speeds), and one way to make components smaller is to make dielectric layers thereof, thinner-and-thinner. As low-dielectric constant (k) material (e.g., silicon dioxide) layers are made thinner to support higher switching speeds, they may be more prone to electron leak-through. This may lead to increased power consumption and also shorter component life. To increase protection, an operating voltage impressed across such components may be decreased. However, this may lead to a decrease in current density, which may disadvantageously offset any frequency increase advantages.

As another alternative to facilitate smaller, higher density chips, a thicker film of higher-k material (e.g., tantalum pentoxide) may be used with an increased channel region control. While high-k material gate insulators may be thicker to block electron leakage at high switching speed, reliable manufacture thereof may be difficult. In addition, device geometry may make it difficult to incorporate such thicker high-k gate insulators. Accordingly, thicker film higher-k materials are not presently a viable solution.

One of the components used with chips, is that of decoupling capacitors. Decoupling capacitance may advantageously serve many purposes, such as serving as an energy reservoir, reducing AC voltage drop (switching noise) of a power/ground path, etc. It has thus far been difficult to provide capacitors on-chip having a required level of decoupling capacitance, and accordingly, decoupling capacitors are mainly provided off-chip, for example, soldered to a printed circuit board (PCB) of a chip package. The placing of such decoupling capacitors close to the die may minimize stray inductance, but often there are physical and layout limitations as to how close the decoupling capacitors can be placed next to the chip on the package's PCB. Accordingly, any attempt to increase capacitance by using increased off-chip surface mount capacitors, may result in inductance problems. Needed are arrangements (e.g., apparatus and methods) to provide on-chip capacitors of increased capacitance.

### BRIEF DESCRIPTION OF THE DRAWINGS

A better understanding of the present invention will become apparent from the following detailed description of example embodiments and the claims when read in connection with the accompanying drawings, all forming a part of the disclosure of this invention. While the following written and illustrated disclosure focuses on disclosing example embodiments of the invention, it should be clearly understood that the same is by way of illustration and example only and that the invention is not limited thereto. The spirit and scope of the present invention are limited only by the terms of the appended claims.

The following represents brief descriptions of the drawings, wherein:

FIG. 1 shows a cross-sectional view of a portion of an example IC chip including example background interconnect structures, such view being useful in gaining a more thorough understanding/appreciation of the present invention;

FIG. 2 is a flow diagram illustrating an example interconnect layer fabrication method to construct a background example on-die capacitor;

FIGS. 3A-3D illustrate an example sequence of cross-sectional views for fabrication of a background on-die capacitor of planar construction, using the FIG. 2 example flow diagram;

FIGS. 4A-4C illustrate three theoretical cross-sectional diagrams useful in comparing amounts of the capacitive area of three different example bottom plate embodiments constructed following an example arrangement/methodology of the present invention;

FIG. 5 illustrates an example (advantageous) bottom electrode etch method useable to construct a patterned, high-aspect ratio, bottom electrode;

FIGS. 6A-6B illustrate two example embodiments of high-aspect ratio bottom electrodes constructed using FIG. 5's example bottom electrode etch method;

FIG. 7 shows a flow chart, similar to FIG. 5, but is for an example sacrificial dielectrics method for construction of an example patterned high-aspect ratio bottom electrode;

FIGS. 8A-8C illustrate an example sequence of cross-sectional views showing fabrication of an example patterned high-aspect ratio bottom electrode using FIG. 7's example sacrificial dielectrics method;

FIG. 9 shows an example flow diagram similar to that of FIG. 2, but such flow diagram incorporates a patterned high-aspect ratio bottom electrode structure such as those illustrated/described in ones of the FIGS. 5-8 examples;

FIGS. 10A-10D illustrate an example sequence of cross-sectional views similar to FIGS. 3A-3D, but show an example sequence for construction of an example interconnect structure incorporating a high-aspect ratio bottom electrode structure for fabrication of a high-aspect ratio on-die capacitor;

FIG. 11 shows an example flow diagram similar to that of FIG. 9, but utilizes fewer operations to achieve a high-aspect ratio on-die capacitor using an etch stop/dielectric together with damascene etch and fill operations;

FIGS. 12A-12C illustrate an example sequence of cross-sectional views to achieve a high-aspect ratio on-die capacitor using the FIG. 11 etch stop/dielectric together with damascene etch and fill operations; and

FIG. 13 illustrates example electronic system arrangements incorporating on-die capacitor(s) implementations of the present invention.

### DETAILED DESCRIPTION

Before beginning a detailed description of the subject invention, mention of the following is in order. When appropriate, like reference numerals and characters may be used to designate identical, corresponding or similar components in differing figure drawings. Further, in the detailed description to follow, example sizes/values/ranges may be given, although the present invention is not limited to the same. As manufacturing techniques (e.g., photolithography) mature overtime, it is expected that devices, apparatus, etc., of smaller size could be manufactured. Well known power/ground connections to ICs and other components may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., flowcharts) are set forth in order to describe example embodiments of the invention, it should be apparent to one skilled in the art that the invention can be practiced without, or with variation of, these specific details. Finally, it should be apparent that software instructions can be used to implement embodiments of the present invention. References in specification, figures, and claims to “top” (e.g., top electrode) and “bottom” (e.g., “bottom electrode”) are indicative of placement of items (e.g., electrodes) in relation to each other with respect to a substrate (representing a bottom direction), and are terms of art, and not indicative of absolute orientation in spatial geometry (e.g., with respect to an earth axis).

Although example embodiments may be described using an example system block diagram in an example processor environment, practice of the invention embodiment is not limited thereto, i.e., the invention embodiments may be able to be practiced with other types of systems, and in other types of analog or digital environments (e.g., non-processor type chips).

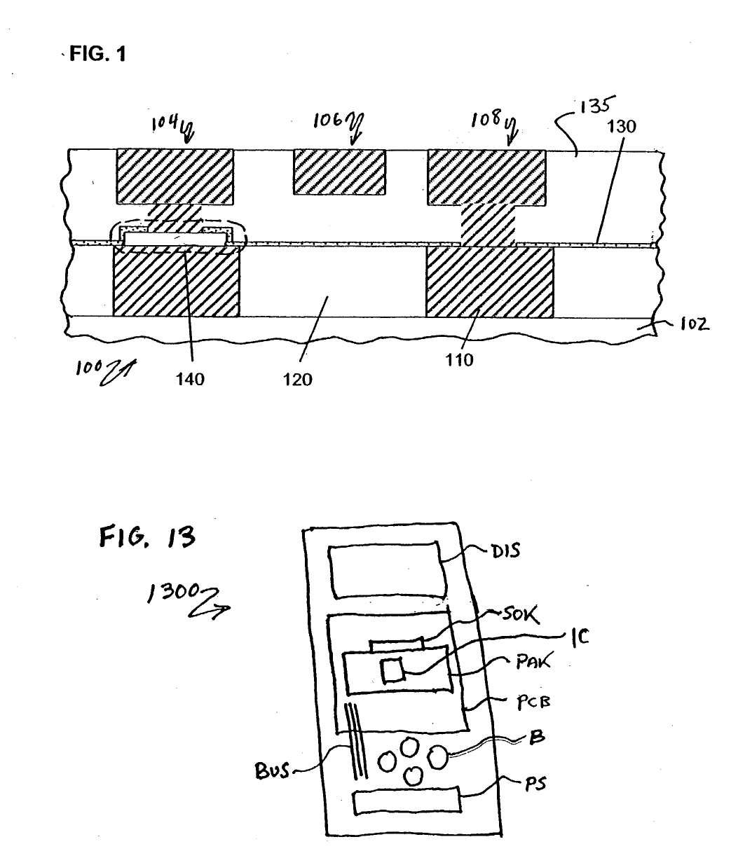

Turning now to the detailed description, FIG. 1 shows a cross-sectional view of a portion of an example IC chip 100 including example background interconnect structures, such view being useful in gaining a more thorough understanding and appreciation of the present invention. More particularly, shown is a substrate 102 which may, for example, contain the circuit of a processor. Further shown are interlayer dielectric (ILD) layers 120, a nitride layer 130, trench layers 135, and also interconnect structures 104, 106, 108 which may be, for example, copper/low-k single and/or dual damascene interconnect structures. Such interconnect structures 104, 106, 108 are used for the purpose of providing electrical connection paths (e.g., power connection paths) from off-chip to the underlying circuit (e.g., processor circuit) below.

For dielectric deposition, a low-k dielectric film may be used both for the ILD layer 120, and for the trench layers 135. A low-k dielectric can be used to provide greater electrical isolation between high current conductive material interconnects than other types of dielectrics enabling greater line density, reduced resistance, and increased device speed. Further, when appropriate, a differing low-k dielectric layer film may be deposited between dielectric structures to act as a barrier to prevent the diffusion of conductive material (e.g., copper), and to provide an etch stop. Trenches may then be formed (e.g., via etching) in the trench layers 135 and/or ILD layer 120 (e.g., for damascene trench etch).

Conductive portions of the interconnect structures may be formed by depositing a liner/barrier layer, a conductive seed layer, and bulk film within damascene trenches, i.e., conductive (e.g., copper) lines inlaid into a nonconductive layer (e.g., low-k dielectric material). After deposition of the conductive layers, annealing may allow the bulk films to achieve optimized conductive characteristics. A planarizing process such as chemical-mechanical polishing (CMP) may be used to remove excess surface conductive material deposited outside of the original trenches. That is, CMP may be used to remove excess conductive material from the surface of the IC being formed so that the only remaining conductive material may be in trench structures formed within the dielectric layers.

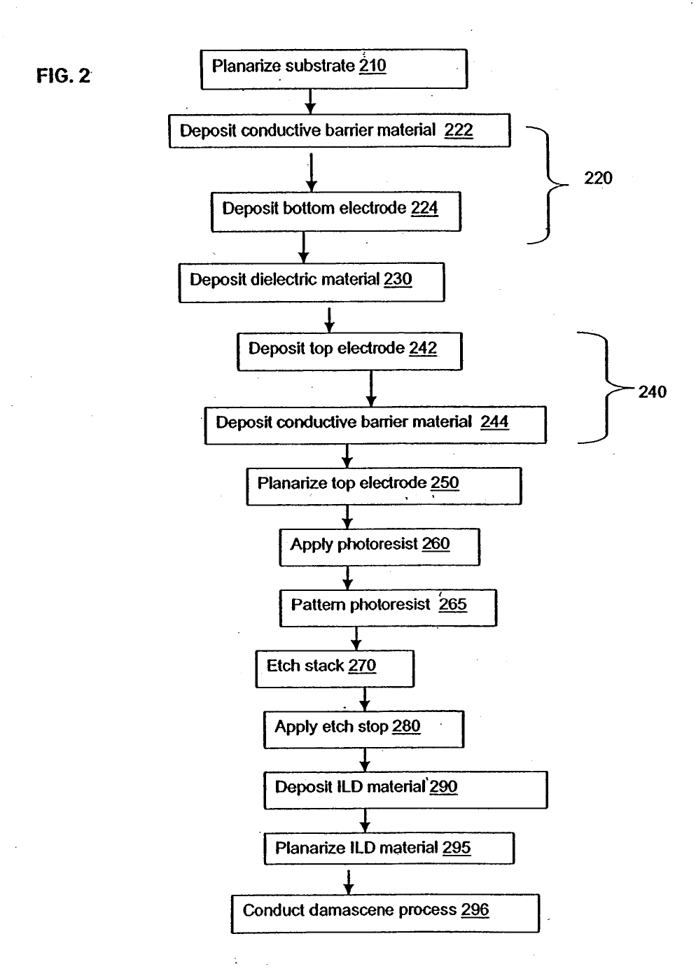

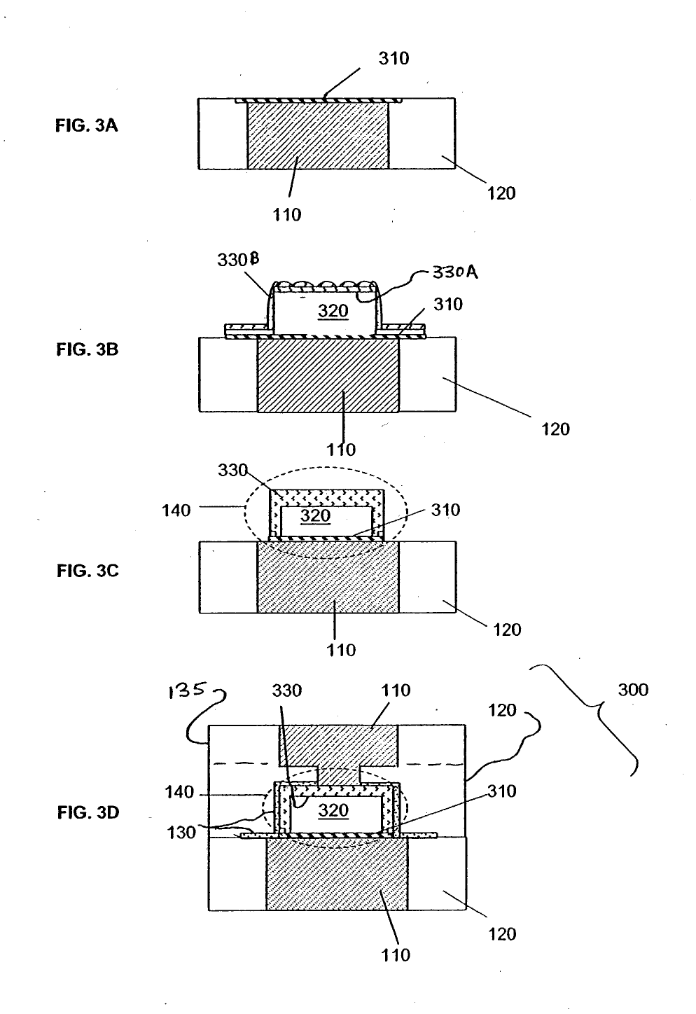

As a further example within FIG. 1, an on-chip planar capacitor 140 may be incorporated as part of interconnect 104 to provide decoupling. As this disclosure is directed toward improvements in on-die capacitors, further discussions focus more specifically on on-die capacitors such as this example background capacitor 140. More particularly, FIG. 2 is a flow diagram illustrating an example interconnect layer fabrication method to construct the background example on-die capacitor 140. Further, FIGS. 3A-3D illustrate an example sequence of cross-sectional views during fabrication of the background on-die capacitor of planar construction, using the FIG. 2 example flow diagram. Discussions now detail such FIGS. 2 and 3A-3D.

More particularly, a substrate (see FIG. 3A), having conductive material (e.g. copper) portions 110 deposited within ILD layers 120, may be substantially planarized (FIG. 2 operation 210). A bottom electrode may then be provided on top of the portion 110, by first depositing (operation 222) a conductive barrier material (not shown) to prevent, for example, oxidation and diffusion of conductive material during deposit of high-k dielectric material. This may be followed by the depositing (operation 224) of a bottom electrode (310) utilizing material that may not oxidize during deposit of high-k material. Alternatively, deposits 222 and 224 may be combined as a single deposit or operation (possible combination being shown representatively by the FIG. 2 designation 220). FIG. 3A is illustrative of fabrication after 210 and 220 (or 210, 222 and 224) including example conductive material 110, ILD material 120, and bottom electrode 310.

Next, depositing, patterning and etching (operation 230) may be performed of a dielectric material 320 (e.g., high-k) of a suitable thickness to achieve a dielectric capacitor body 320 (FIG. 3B) providing a desired electrode separation. Further, a top electrode also may be deposited in two parts with the deposit (operation 242) of a first electrode material 330A that will resist oxidation, followed by deposit (operation 244) of conductive barrier material 330B to inhibit diffusion of conductive material. Alternatively, as was mentioned previously with respect to the bottom electrode fabrication, deposits 242 and 244 may be combined as a single deposit or operation (possible combination being shown representatively by the FIG. 2 designation 240). FIG. 3B illustrates a construction after FIG. 2's 230 and 240 (or 230, 242 and 244) with deposit of dielectric material 320 followed by deposit of material for a top electrode 330.

The top electrode 330 (FIG. 3C) may then be annealed and/or planarized (operation 250) to improve planarity to simplify subsequent patterning, and to reduce film stress. A photoresist may be applied (operation 260) and then patterned (operation 265) to transfer an image from a mask to the photoresist. Etching (operation 270) of the resulting stack may follow, to result in stacked capacitor 140 (FIG. 3C) having a bottom electrode 310, a dielectric body 320, and a top electrode 330. FIG. 3C illustrates the structure after FIG. 2's 250 through 270, including planarization 250 of the top electrode followed by application 260, and patterning 265, of photoresist.

An example silicon nitride layer 130 (FIG. 3D) may be thereafter applied (operation 280) as an etch stop, followed by deposit (operation 290) of additional ILD 120 and/or trench layers 135 material. Planarizing (operation 295) may be applied to the additional ILD 120 and/or trench layers 135, to improve a planarity of the IC chip. Thereafter, damascene processes (operation 296) may be conducted to form the additional conductive material portions 110, to allow connections to the off-chip world. That is, single and/or dual damascene trench etch processes, followed by filling of the trenches with conductive material, and then excess material removal (e.g., via CMP), may be conducted. FIG. 3D illustrates a structure 300 resulting after FIG. 2's 280 through 296 operations with application 280 of an etch stop (e.g., silicon nitride layer), deposit 120 of ILD material, and planarization 295, followed by a damascene process 296 (e.g., Cu dual damascene process). Such structure 300 includes the stacked planar capacitor 140.

As mentioned previously, a sufficient capacitance is required of an on-chip capacitor to make it a viable substitute for off-chip capacitors. For example, sufficient capacitance may be required to accomplish desired decoupling. The FIG. 3D planar style capacitor may be disadvantageous in that to achieve a necessary capacitance, undesirable use of a high-k material may be required. However, as mentioned previously, reliable manufacturing using high-k material may be difficult. Another possible approach to increase capacitance is to increase a chip area size (i.e., a footprint) of the planar capacitor. That is, as capacitance is proportional to free space permittivity, the dielectric constant and area, and is inversely proportional to thickness, then to increase a capacitance without using high-k materials, a capacitance area can be increased. However, as chip real estate is a commodity in chip design/manufacturing, an increase in the chip area size (i.e., footprint) of the capacitor is not a desirable solution.

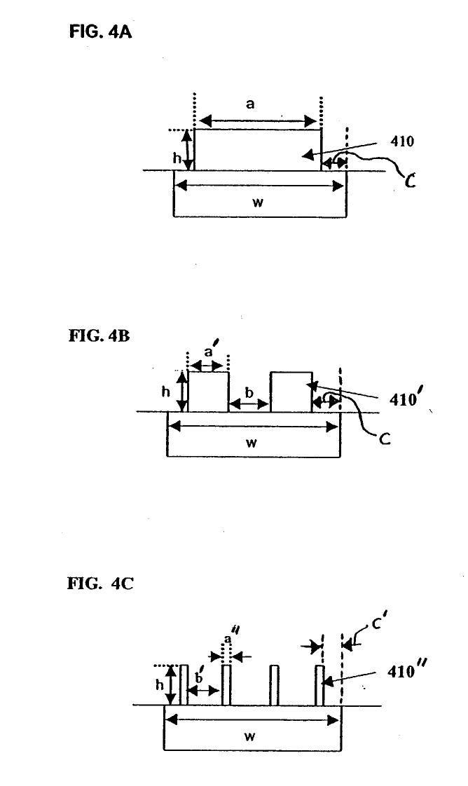

Discussion turns now to viable on-chip capacitor solutions, and first begins with theoretical illustrations and discussions to show example arrangements with increased capacitive area. More particularly, FIGS. 4A-4C illustrate three theoretical cross-sectional diagrams useful in comparing amounts of the capacitive area of three different example bottom plate embodiments constructed following the arrangement/methodology of the present invention.

More particularly, such example embodiments each include at least one conductive extension that extends from the bottom electrode toward the top electrode in an effort to increase capacitive area within a given chip area size (i.e., footprint). It is noted that FIGS. 4A-4C illustrate a number of dimensional notations. For example, a notation “a” represents a conductive extension width, “b” represents a spacing distance between neighboring conductive extensions, “c” represents a displacement distance of the conductive extension from an outer edge of the bottom electrode width, and “h” represents a height of the conductive extension. In the discussions to follow, it is assumed that each of the FIGS. 4A-4C theoretical embodiments have a mutually matching height “h” such that the differing theoretical embodiments can be more readily compared to one another. A depth dimension of the conductive extension (extending in a direction into the drawing) is not illustrated for sake of simplicity/clarity. Further, structures are not shown drawn to scale, and in fact, some structures may be exaggerated for clarity. In addition, structures may be non-planar, but may be shown as substantially planar for clarity. Discussion will now show increased capacitive length with respect to two-dimensional directions; paralleling analysis may be used to likewise understand increased capacitive area in three dimensions.

More particularly, viewing the FIG. 4A theoretical bottom electrode illustration, note that the previously described FIG. 3D capacitor (without any conductive extensions) would have a capacitive length (CL) of simply CL=w. Advantageously, the FIG. 4A theoretical bottom electrode having one rectangular conductive extension and the same footprint has an increased CL=c+h+a+h+c. That is, in tracing a c+h+a+h+c path along the bottom electrode and then up and over the conductive extensions 410, and in realizing that the lengths c+a+c are equivalent in length to w, then it can be seen that h+h represents an increase in CL over the planar capacitor (without any conductive extensions). Hence, the extended bottom electrode can be said to have a high-aspect ratio. By varying the height h, variable amounts of increased capacitance can be achieved.

Turning next to FIG. 4B, such theoretical bottom electrode having two block-like conductive extensions has an increased CL=c+h+a′+h+b+h+a′+h+c. That is, in tracing a c+h+a′+h+b+h+a′+h+c path along the bottom electrode and then up and over the two conductive extensions 410′, and in realizing that the lengths c+a′+b+a′+c are equivalent in length to a planar capacitor of width w, then it can be seen that h+h+h+h represents an increase in CL over the planar capacitor (without any conductive extensions), and h+h represents an increase in CL over the FIG. 4A theoretical electrode. Again, such extended bottom electrode can be said to have a high-aspect ratio, and by varying the height h, variable amounts of increased capacitance can be achieved.

Turning finally to FIG. 4C, FIG. 4C shows four times the capacitor extensions 410″ than FIG. 4A. This theoretical bottom electrode has an increased CL=c′+h+a″+h+b′+h+a″+h+b′+h+a″+h+b′+h+a″+h+c′ due to the four finger-like conductive extensions. That is, in tracing a c′+h+a″+h+b′+h+a″+h+b′+h+a″+h+b′+h+a″+h+c′ path along the bottom electrode and then up and over the four finger-like conductive extensions 410″, and in realizing that the lengths c′+a″+b′+a″+b′+a″+b′+a″+c′ are equivalent in length to a planar capacitor of width w, then it can be seen that h+h+h+h+h+h+h+h represents the increase in CL over the planar capacitor (without any conductive extensions). Again, variable amounts of increased capacitance can be achieved by varying the height h. While the FIG. 3C arrangement may give increased CL and a further increased high-aspect ratio, such may be at a cost of additional manufacturing steps as will become more apparent in the description ahead.

While the FIGS. 4A-4C examples utilize rectangular, block and finger shaped conductive extensions and extensions numbering one, two or four, practice of embodiments of the present invention are no way limited to such shapes or numbers of extensions. That is, any type of projection shape, and any number of projections may be used. Further, projections that are inconsistent with one other in shape, size, length, e.t.c., may also be utilized in practice of the present invention.

It should be noted at this point that the non-planar components (e.g., extensions) of the present invention are intentionally designed components specifically directed to result in substantial non-planarity of the electrodes. This is opposed to inadvertent unappreciated irregularities which may result in other capacitors, e.g., from inconsequential sub-layers irregularities carrying upwards to subsequently formed layers.

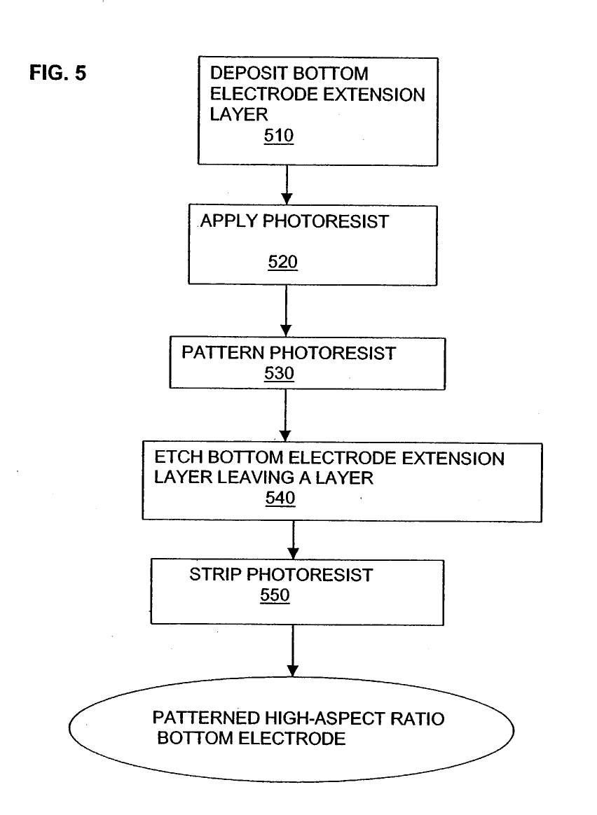

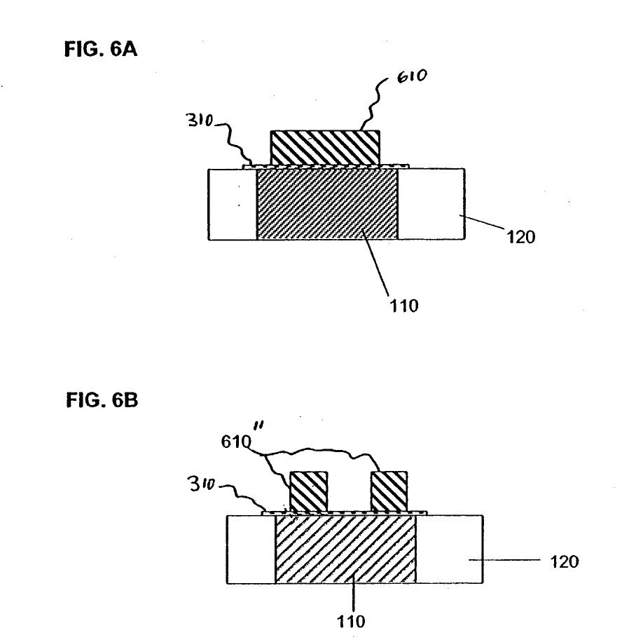

Continuing discussions, FIG. 5 illustrates an example (advantageous) bottom electrode etch method useable to construct a patterned, high-aspect ratio, bottom electrode that can then be used as a template for an example (advantageous) three-dimensional capacitor stack. Relatedly, FIGS. 6A-6B illustrate two example embodiments of high-aspect ratio bottom electrodes constructed using FIG. 5's example bottom electrode etch method. Discussions now detail such FIGS. 5 and 6A-6B.

In such a FIG. 5 methodology, assume that a thin bottom electrode is already provided on top of a substrate, like that shown by FIG. 3A. As one example, the bottom electrode may have an uneven surface or curved geometry. Thereafter, deposition (operation 510) may be performed to achieve a conductive extension layer of desired conductive material (e.g., copper) that is electrically and mechanically connected to the thin bottom electrode, and of a desired extension thickness h (e.g., 400-500 angstroms). A photoresist may then be applied (operation 520) to the conductive extension layer followed by patterning (operation 530) of the photoresist. The conductive extension layer may then be etched (operation 540) with a timed etch process so as to leave, for example, a single or multiple conductive extensions electrically and mechanically attached to the thin bottom electrode. Subsequently, the photoresist may be stripped (operation 550), for example, chemically stripped. This process may result in a patterned, high-aspect ratio, bottom electrode that may then serve as a template for a high-aspect capacitor architecture. Bottom electrode materials can include, but are not limited to TaN, TiN, Ru, RO₂, Ir, IrO₂, Ta—Ir—O, W, Pt, TiN, W, WN, WC, e.t.c.

More particularly, FIG. 6A illustrates an example extended bottom electrode having a single extension similar to the FIG. 4A theoretical electrode, and includes thin bottom electrode 310, bottom electrode conductive extension 610 on top of a conductive material 110 and ILD 120. FIG. 6B is similar, but includes two bottom electrode conductive extensions 610″, resulting in an example extended bottom electrode similar to the FIG. 4B theoretical electrode.

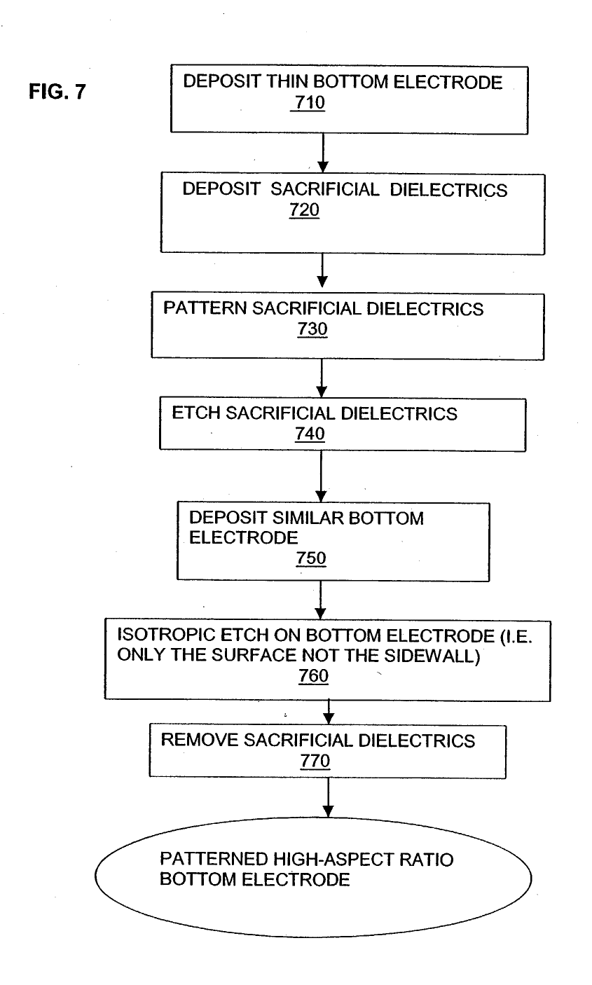

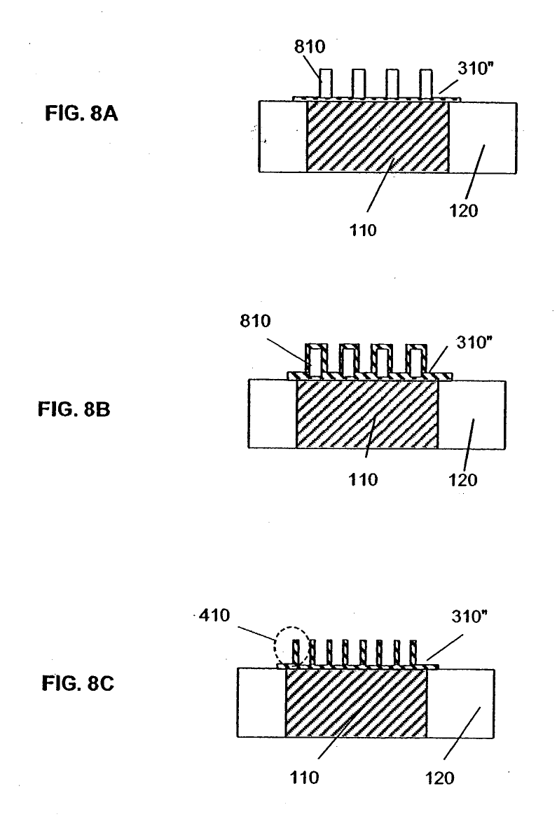

FIG. 7 shows a flow chart, similar to FIG. 5, for a differing example sacrificial dielectrics method for construction of a patterned, high-aspect ratio, bottom electrode. With such a sacrificial dielectrics methodology, it may be possible to obtain a denser pattern structure (c.f., FIG. 4C with FIG. 4A or 4B) than that obtained with the FIG. 5 bottom electrode etch method. Such denser pattern structure results in increased capacitive area, and consequently, increased capacitance. FIGS. 8A-8C illustrate an example sequence of cross-sectional views showing fabrication of an example patterned high-aspect ratio bottom electrode using FIG. 7's example sacrificial dielectrics method. Discussions now detail such FIGS. 7 and 8A-8C.

Turning now to more detailed discussion of FIG. 7, deposition (operation 710) may be performed of desired conductive material (e.g., copper) to achieve a thin bottom electrode. For example, a bottom electrode deposited with a sacrificial dielectric method 710 can be thinner than a bottom electrode deposited otherwise (e.g., 50, 100, 150 . . . angstroms versus 400, 500, 600 . . . angstroms). Thereafter, there may be deposition 720 of sacrificial dielectrics on top of the bottom electrode, with the bottom electrode serving as an oxygen barrier. The sacrificial dielectrics may be subsequently patterned 730 (e.g., using photo resist), and etched 740. FIG. 8A illustrates an example structure having sacrificial dielectrics 810 resulting from operations 710 through 740.

After the etching, another bottom electrode layer of similar composition to the bottom electrode previously deposited (in operation 710), may be deposited (operation 750) on the patterned sacrificial dielectrics 810 as well as any exposed portions of the previous bottom electrode layer. FIG. 8B illustrates an example configuration, after operation 750, with deposition of a similar material bottom electrode as had been previously deposited.

This combined bottom electrode structure may then be etched (operation 760), using, for example, an isotropic etch process. That is, the isotropic etch has a directional etching preference such that any horizontally exposed surfaces of the combined bottom electrode layers are etched, while vertically oriented surfaces are not (or less) etched. One important result is that the caps of the bottom electrode layer which previously existed upon the tops of the sacrificial dielectric extensions 810 have now been removed so that the sacrificial dielectric extension material is now exposed.

The sacrificial dielectrics may be subsequently removed (operation 770), using, for example, etching, resulting in a patterned, high-aspect ratio, bottom electrode 310″ having thin vertical conductive fingers 410 extending from the major planar surface of the bottom electrode. FIG. 8C illustrates such example capacitor extensions 410 that may (once the high-aspect ratio capacitor is completed) inter-mate, or partially inter-mate, with, and electrically oppose, extensions from an other electrode. This high-aspect bottom electrode can now serve as a high-aspect template for continued construction of high capacitance on-die capacitor.

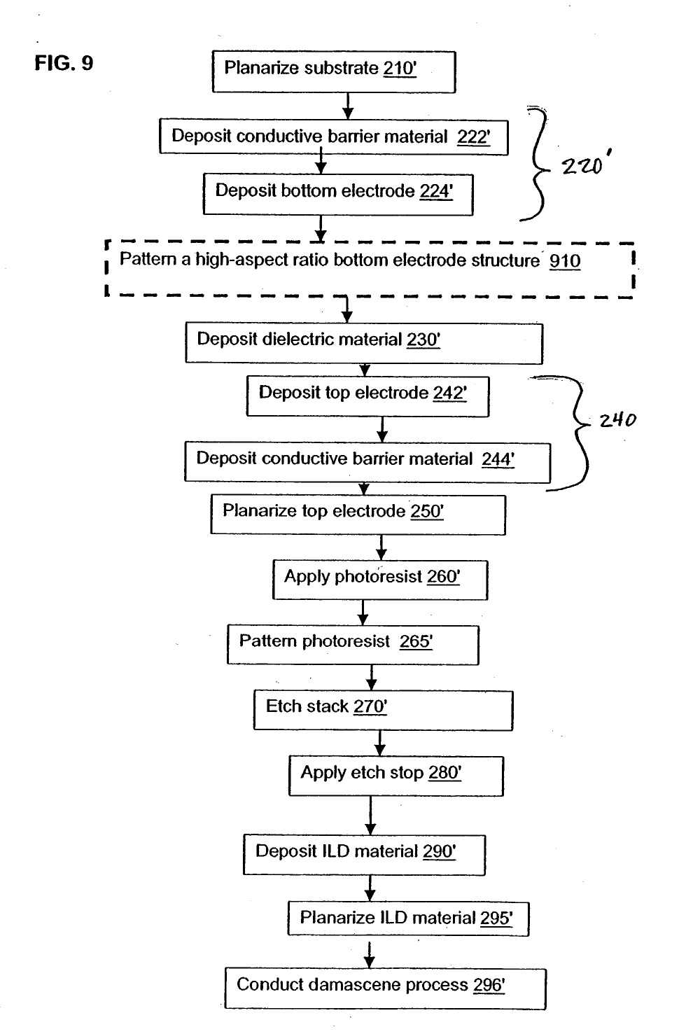

FIG. 9 shows a methodology, similar to that shown in FIG. 2, but incorporates (operation 910) a patterned, high-aspect ratio, bottom electrode structure such as that which can result from the process shown in FIGS. 5-6, or alternatively, shown in FIGS. 7-8. That is, any patterned, high-aspect ratio, bottom electrode structure can serve as a template for further construction of a high-aspect on-chip capacitor.

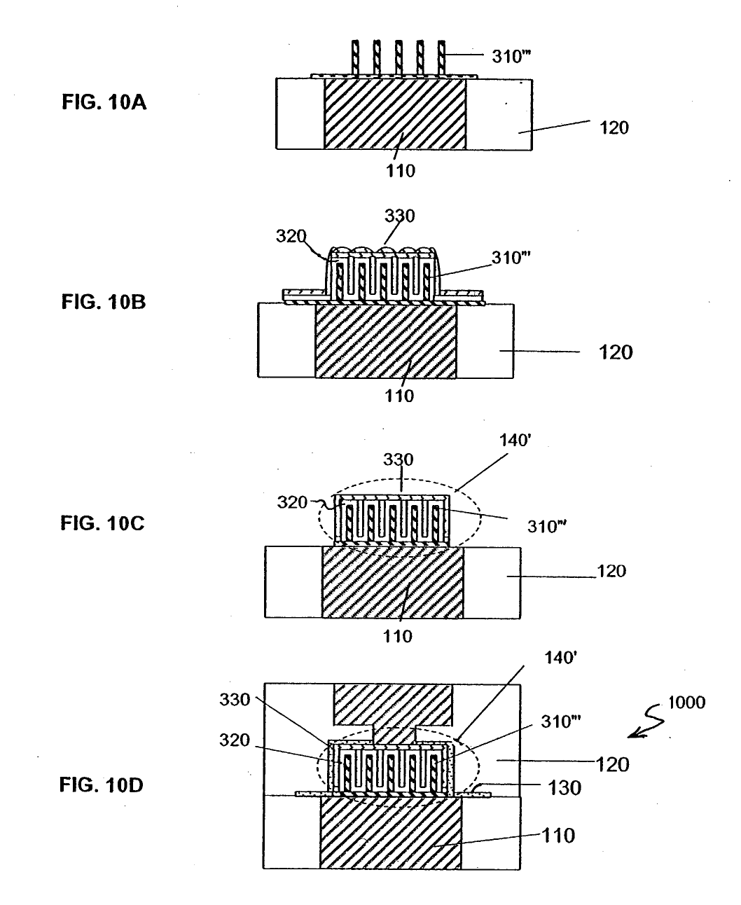

Relatedly, FIG. 10 is an illustration similar to FIG. 3, but showing cross-section examples using FIG. 9 methodology for construction of an interconnect structure incorporating a high-aspect ratio, bottom electrode structure for fabrication of a high-aspect ratio on-die capacitor. The magnitude of a high-aspect ratio that can be fabricated is dependent on factors including bottom electrode properties such as the mechanical strength of the bottom electrode, or the deposition or etch process utilized. An example high-aspect ratio that could be attained may be 3:1, 4:1, 5:1 . . . 10:1, . . . . and even 15:1, but is not limited by such.

Turning now to more detailed discussions, FIG. 10A illustrates an example configuration resulting from the FIG. 9 operations 210′ through 910, with construction of a template of high-aspect bottom electrode 310′″ on conductive material 110, and ILD material 120. FIG. 10B illustrates a construction after FIG. 9's 230′ and 240′ (or 230′, 242′ and 244′), with deposit of dielectric material 320, followed by deposit of material for a top electrode 330. The dielectric material 320 acts as a capacitive dielectric material for the resultant capacitor.

FIG. 10C illustrates a fabrication, after FIG. 9's 250′ through 270′, indicating planarization of a top electrode 330, followed by application and patterning of photoresist, in 260′ and 265′ and etch in 270′. Such process may result in an on-chip, high-aspect capacitor 140′. FIG. 10D shows a cross-section of a high-aspect ratio capacitor interconnect structure 1000, resulting after FIG. 9's 280′ through 296′, with application 280′ of an etch stop (e.g., silicon nitride layer), and deposit of ILD material 120, and planarization 295′ followed by a damascene process 296′ (e.g., Cu single and/or dual damascene process).

While the FIGS. 10B-10D (and other FIGs) examples illustrate bottom and top electrode extensions which totally inter-mate and electrically oppose each other along an entirety of the extensions, practice of the present invention is not limited thereto, and in fact, partial inter-mating and electrically opposing may be advantageously used to vary/customize a capacitance of a resultant non-planar capacitor. For example, one of the electrodes (e.g., the bottom electrode) may be provided of predetermined size/shape/extension(s), while the other of the electrodes (e.g., the top electrode) may be provided of a variable size/shape/extension(s) to vary/customize capacitance. Either, or both of the electrodes, and the dielectric may be non-planar having a curved surface.

As a first example, if the FIG. 7 operation 770 of removing the sacrificial dielectrics 810 is only partially conducted so as to etch away only a top portion (e.g., top half) of the sacrificial dielectrics 810, then any formed top electrode extensions will be shorter in length than the bottom electrode extensions. Hence, as there would be less opposing electrode area, a capacitance of a resulting capacitor would be reduced. As a second example, rather than varying an extension length of one of the electrodes, a number of extensions thereof may instead be varied. For example, a bottom electrode may be formed with eight (8) extensions (like that shown in FIG. 8C), while (through selective patterning/etching) a top electrode may be formed with six (6) extensions. Of course, varying a capacitive dielectric thickness and/or material may also be used to vary/customize a capacitance of embodiments of the present invention.

As shown in FIG. 10, the methodology of FIG. 5 and FIG. 7, and the bottom electrode, high-aspect template subsequently formed, enable dielectric material, and subsequently the top electrode, to be formed in a geometrically variable pattern other than planar (e.g., curved, serpentine, sandwiched). A resulting three-dimensional capacitor stack can now have increased capacitive surface area with an associated increase in capacitance for a given width or area (i.e., footprint).

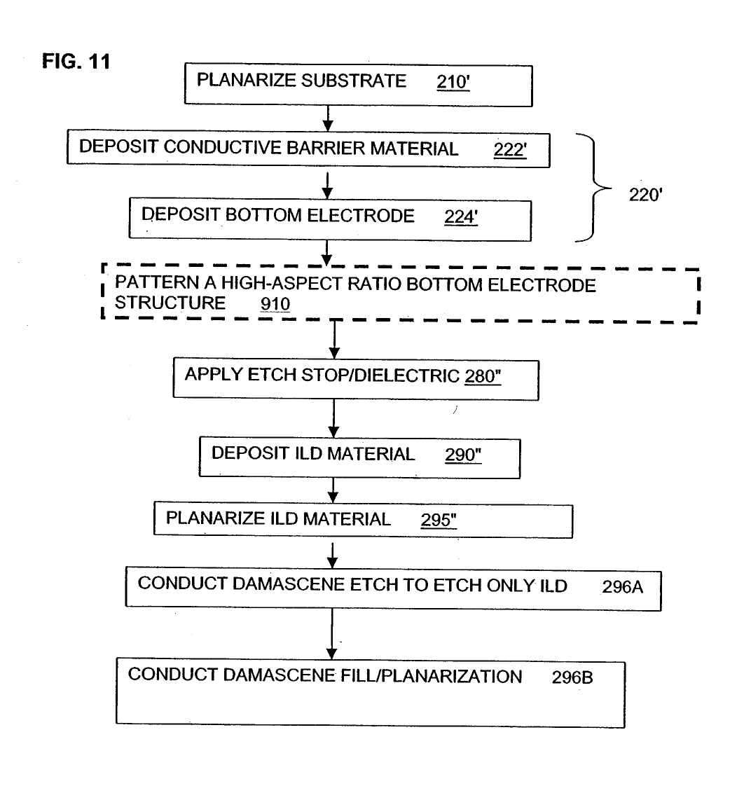

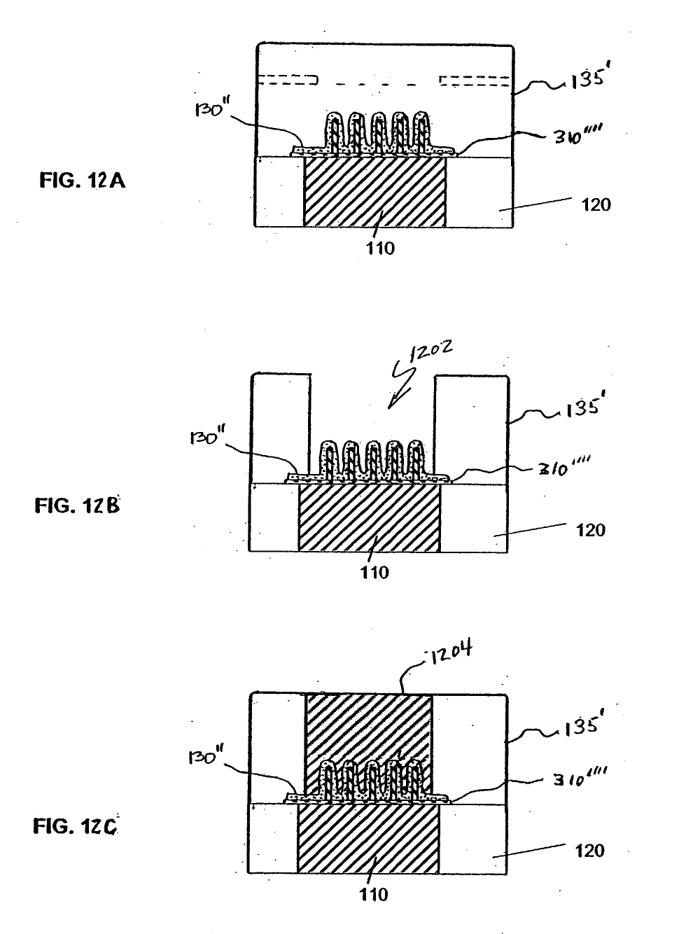

FIG. 11 shows an example flow diagram similar to that of FIG. 10, but utilizes fewer operations to achieve a high-aspect ratio on-die capacitor using an etch stop/dielectric together with damascene etch and fill operations. Relatedly, FIGS. 12A-12C illustrate an example sequence of cross-sectional views to achieve a high-aspect ratio on-die capacitor using the FIG. 11 etch stop/dielectric together with damascene etch and fill operations. Discussion now details FIGS. 11 and 12A-12C.

More particularly, the first four operations of 210′, 222′, 224′ and 910 are the same as those of the previously discussed FIG. 9, to begin with a bottom-electrode/extension arrangement such as that shown in FIG. 10A. Next, there is applied an etch-stop/dielectric layer 130″ (operation 280″), then an ILD material layer 135′ (operation 290″) and planarization (operation 295″) for an example result such as that shown in FIG. 12A.

As to the etch-stop/dielectric layer 130″, such layer will serve two differing purposes in this example embodiment of the invention. First, the layer will serve as an etch-stop during subsequent damascene trench etch processes (discussed ahead). Second, the layer will ultimately serve as sandwiched dielectric layer of the high-aspect ratio on-die capacitor. Materials containing nitride, for example, may be suitable to serve such dual purpose.

As to the ILD material layer 135′, such may be deposited in a single layer (in single damascene processes) or as multiple layers (e.g., in dual damascene processes). Dashed lines within FIG. 12A are for the purpose of representatively showing an intermediate nitride (window) layer and dual dielectric layers of a dual damascene process. However, for simplicity and clarity of illustration and discussion, these example discussions and FIGS. 12B-C will focus on a single damascene process.

After deposition of the ILD material layer 135′, a resist is applied/patterned, and then a timed etch process is applied to form a damascene trench 1202, with an example result as shown in FIG. 12B (operation 296A). The etch-stop/dielectric layer 130″ is advantageous in that it serves as an etch stop, allowing the original bottom-electrode/extension arrangement coated with the layer 130″ to be exposed at the bottom of the damascene trench 1202 substantially devoid of any ILD material. That is, the applied dielectric etch may have a high selectivity (preference) for the dielectric material as opposed to the etch-stop (e.g., nitride) layer.

Next, a barrier layer may be needed within the damascene trench. More particularly, if silicon dioxide is used as the ILD material layer 135′, and if copper, for example, is to be used for subsequent damascene deposition, then a barrier layer may be needed because copper is an excellent diffuser in silicon dioxide. Such barrier layer (not shown in the drawings) may coat an entirety of sidewalls of the trench 1202, and may likewise coat the exposed layer 130″. It may be possible that either an electrically insulator material or an electrically conductive material may be used as the barrier layer. In the event that an electrically insulator material is used, then any such material deposited onto the exposed layer 130″ can advantageously contribute to the thickness/body of the sandwiched dielectric of a subsequently formed high-aspect ratio on-die capacitor. In the opposite event that an electrically conductive material is used, then any such material deposited onto the exposed layer 130″ can advantageously contribute to the upper electrode body of a subsequently formed high-aspect ratio on-die capacitor.

After formation of any barrier layer, conductive portions of the interconnect structures may be formed by depositing a conductive seed layer and bulk film within damascene trenches, i.e., conductive (e.g., copper) lines inlaid into a nonconductive layer (e.g., low-k dielectric material). After deposition of the conductive layers, annealing may allow the bulk films to achieve optimized conductive characteristics. A planarizing process such as chemical-mechanical polishing (CMP) may be used to remove excess surface conductive material deposited outside of the original trenches (operation 296B). That is, CMP may be used to remove excess conductive material from the surface of the IC being formed so that the only remaining conductive material may be in trench structures formed within the dielectric layers. An example result is as shown in FIG. 12C, where there has been formed a high-aspect ratio on-die capacitor which includes a high-aspect ratio bottom electrode 310″″, sandwiched dielectric layer 130″, and a high-aspect ratio upper damascene electrode 1204. That is, the upper electrode 1204 is a damascene-formed electrode.

FIG. 13 illustrates example electronic system arrangements incorporating on-die capacitor(s) implementations of the present invention. More particularly, shown is an integrated circuit (IC) chip system incorporating one or more on-die capacitors. Such IC may be part of an electronic package PAK system incorporating the IC together with supportive components onto a printed circuit board (PCB). The package PAK may be mounted via a socket SOK onto an electronic system PCB (e.g., motherboard system (MB)). The system PCB may be part of an electronic device (e.g., computer, electronic consumer device, server, communication equipment) system that includes at least one input (e.g., user buttons B), at least one output (e.g., display DIS), a bus BUS and a power supply PS.

In beginning to conclude, the example (advantageous) embodiment capacitor stack (e.g., bottom electrode, dielectric, and top electrode) can be inserted between metal layers in the backend of the chip interconnections. Fabrication may not require extra chip area or an extra layer, as required when using a gate dielectric. The example embodiment can result in an increase in capacitance without requiring an increased footprint, as would other on-chip de-coupling capacitors. In addition, the capacitor stack can be located closer to the power than an off-chip surface mount capacitor, thereby lessening inductive variations. Further, the example (advantageous) capacitor stack may have less leakage without extra utilization of die area, than that of a gate dielectric. In addition, capacitance may be increased, without necessitating incorporation of high-k materials, and thusly, avoiding electron mobility problems and degradation of transistor performance due to charge trapping. Such example capacitor stack can function in conjunction with other chip, and package, capacitors.

At least a portion (if not all) of the present invention may be practiced as a software invention, implemented in the form of a machine-readable medium having stored thereon at least one sequence of instructions that, when executed, causes formation of on-chip capacitors of the present invention during IC manufacturing. With respect to the term “machine”, such term should be construed broadly as encompassing all types of machines, e.g., a non-exhaustive listing including: computing machines, non-computing machines, communication machines, etc. A “machine-readable medium” includes any mechanism that provides (i.e., stores and/or transmits) information in a form readable by a machine (e.g., a processor, computer, electronic device). Such “machine-readable medium” term should be broadly interpreted as encompassing a broad spectrum of mediums, e.g., a non-exhaustive listing including: electronic medium (read-only memories (ROM), random access memories (RAM), flash cards); magnetic medium (floppy disks, hard disks, magnetic tape, etc.); optical medium (CD-ROMs, DVD-ROMs, etc); electrical, optical, acoustical or other form of propagated signals (e.g., carrier waves, infrared signals, digital signals); e.t.c.

In concluding, reference in the specification to “one embodiment”, “an embodiment”, “example embodiment”, e.t.c., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment and/or component, it is submitted that it is within the purview of one skilled in the art to effect such feature, structure, or characteristic in connection with other ones of the embodiments or components. Furthermore, for ease of understanding, certain method procedures may have been delineated as separate procedures; however, these separately delineated procedures should not be construed as necessarily order dependent in their performance, i.e., some procedures may be able to be performed in an alternative ordering, simultaneously, e.t.c.

This concludes the description of the example embodiments. Although the present invention has been described with reference to a number of illustrative embodiments thereof, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention.

In addition to variations and modifications in the component parts and/or arrangements, alternative uses can also be apparent to those skilled in the art. For example, the method for forming a high-aspect component utilizing a bottom electrode template can be utilized for formation of other components. In addition, the high-aspect capacitor can be alternatively fabricated as a discrete component and added to a system instead of another discrete component. In another example, a die dedicated to providing interconnect paths and stackable/bondable onto other die, may be manufactured with a one or a plurality of the high-aspect capacitors provided at predetermined locations to give a desired interconnect/capacitor arrangement. Further, while the above example embodiments describe formation of a bottom electrode, then a dielectric capacitor layer, and finally a top electrode, the operations may be easily reversed with the top electrode being formed first.

What is claimed is:

1. An on-die capacitor comprising:
a non-planar first electrode;
a capacitive dielectric layer; and
a non-planar second electrode, wherein at least a portion of the capacitive dielectric layer is between the non-planar first electrode and the non-planar second electrode.

2. A capacitor as claimed in claim 1:
wherein the non-planar first electrode has at least one extension extending toward the non-planar second electrode; and
wherein the non-planar second electrode has at least one extension extending toward the non-planar first electrode.

3. A capacitor as claimed in claim 2:
wherein the at least one extension of one of the non-planar first electrode and second electrode, inter-mates and electrically opposes at least one extension of the other non-planar first electrode and second electrode.

4. A capacitor as claimed in claim 3:
wherein all extensions of one of the non-planar first electrode and second electrode inter-mate and electrically oppose extensions of the other non-planar first electrode and second electrode, wherein at least a portion of the capacitive dielectric layer is between the non-planar first electrode and the non-planar second electrode.

5. A capacitor as claimed in claim 1:
wherein the capacitive dielectric layer substantially conforms to a geometry of the nonplanar first electrode; and
wherein the non-planar second electrode substantially conforms to a geometry of the capacitive dielectric layer.

6. A capacitor as claimed in claim 1:
wherein at least one of the non-planar first electrode and non-planar second electrode is a high-aspect-ratio patterned electrode.

7. A capacitor as claimed in claim 1:
wherein the capacitor is part of conductive interconnect layers of an integrated circuit (IC).

8. A capacitor as claimed in claim 1:
wherein at least one of the non-planar first electrode and non-planar second electrode is a damascene-formed electrode.

9. An integrated circuit (IC) comprising:
an on-die capacitor including:
a non-planar first electrode;
a capacitive dielectric layer; and
a non-planar second electrode.

10. An IC as claimed in claim 9:
wherein the non-planar first electrode has at least one extension extending toward the non-planar second electrode; and
wherein the non-planar second electrode has at least one extension extending toward the non-planar first electrode.

11. An IC as claimed in claim 10:
wherein the at least one extension of one of the non-planar first electrode and second electrode, inter-mates and electrically opposes at least one extension of the other non-planar first electrode and second electrode.

12. An IC as claimed in claim 11:
wherein all extensions of one of the non-planar first electrode and second electrode inter-mate and electrically oppose extensions of the other non-planar first electrode and second electrode.

13. An IC as claimed in claim 9:
wherein the capacitive dielectric layer substantially conforms to a geometry of the non-planar first electrode; and
wherein the non-planar second electrode substantially conforms to a geometry of the capacitive dielectric layer.

14. An IC as claimed in claim 9:
wherein at least one of the non-planar first electrode and non-planar second electrode is a high-aspect-ratio patterned electrode.

15. An IC as claimed in claim 9:
wherein the capacitor is part of conductive interconnect layers of the IC.

16. An IC as claimed in claim 9:
wherein at least one of the non-planar first electrode and non-planar second electrode is a damascene-formed electrode.

17. An IC as claimed in claim 9:
wherein the IC is one of a processor IC, communication IC and chip set.

18. A system comprising:
at least one of a socket, bus portion, input device, output device and PCB; and
an on-die capacitor including:
a non-planar first electrode;
a capacitive dielectric layer; and
a non-planar second electrode, wherein at least a portion of the capacitive dielectric layer is between the non-planar first electrode and the non-planar second electrode.

19. A system as claimed in claim 18:
wherein the non-planar first electrode has at least one extension extending toward the non-planar second electrode; and
wherein the non-planar second electrode has at least one extension extending toward the non-planar first electrode.

20. A system as claimed in claim 19:
wherein the at least one extension of one of the non-planar first electrode and second electrode, inter-mates and electrically opposes at least one extension of the other non-planar first electrode and second electrode.

21. A system as claimed in claim 20:
wherein all extensions of one of the non-planar first electrode and second electrode inter-mate and electrically oppose extensions of the other non-planar first electrode and second electrode.

22. A system as claimed in claim 18:
wherein the capacitive dielectric layer substantially conforms to a geometry of the non-planar first electrode; and
wherein the non-planar second electrode substantially conforms to a geometry of the capacitive dielectric layer.

23. A system as claimed in claim 18:
wherein at least one of the non-planar first electrode and non-planar second electrode is a high-aspect-ratio patterned electrode.

24. A system as claimed in claim 18:
wherein the capacitor is part of conductive interconnect layers of an integrated circuit (IC).

25. A system as claimed in claim 18:
wherein at least one of the non-planar first electrode and non-planar second electrode is a damascene-formed electrode.

26. A system as claimed in claim 18:
wherein the system is one of an electronic a package system, a system printed circuit board (PCB), and an electronic device.

27. A method comprising:
forming a non-planar first electrode;
forming a capacitive dielectric layer; and
forming a non-planar second electrode, wherein at least a portion of the capacitive dielectric layer is formed between the non-planar first electrode and the non-planar second electrode.

28. A method as claimed in claim 27:
wherein the non-planar first electrode has at least one extension extending toward the non-planar second electrode; and
wherein the non-planar second electrode has at least one extension extending toward the non-planar first electrode.

29. A method as claimed in claim 28:
wherein the at least one extension of one of the non-planar first electrode and second electrode, inter-mates and electrically opposes at least one extension of the other non-planar first electrode and second electrode.

30. A method as claimed in claim 29:
wherein all extensions of one of the non-planar first electrode and second electrode inter-mate and electrically oppose extensions of the other non-planar first electrode and second electrode.

31. A method as claimed in claim 27:
wherein the capacitive dielectric layer substantially conforms to a geometry of the non-planar first electrode; and
wherein the non-planar second electrode substantially conforms to a geometry of the capacitive dielectric layer.

32. A method as claimed in claim 27:
wherein at least one of the non-planar first electrode and non-planar second electrode is a high-aspect-ratio patterned electrode.

33. A method as claimed in claim 27:
wherein the capacitor is formed as part of conductive interconnect layers of an integrated circuit (IC).

34. A method as claimed in claim 27:
wherein at least one of the non-planar first electrode and non-planar second electrode is formed as a damascene-formed electrode.
